(19) United States
(12) Patent Application Publication
(10) Pub. No.: US 2013/0011582 A1
(43) Pub. Date: Jan. 10, 2013

(54) CRUCIBLE, VAPOR DEPOSITION SYSTEM AND METHOD USING THE CRUCIBLE

(75) Inventor: JUIN-HONG LIN, Tu-Cheng (TW)

(73) Assignee: HON HAI PRECISION INDUSTRY CO., LTD., Tu-Cheng (TW)

(21) Appl. No.: 13/248,044

(22) Filed: Sep. 29, 2011

(30) Foreign Application Priority Data
Jul. 7, 2011 (TW) 100123972

(51) Int. Cl. C23C 16/448; B23K 15/00

(52) U.S. Cl. 427/596; 118/723 FE; 219/121.21

(57) ABSTRACT

A crucible includes a hollow main body defining an opening, a heat body, and a cover. The heat body is received in and connected with the main body. The heat body includes a heat end extending out of the main body through the opening. The heat end can be heated by an electro-beam. The cover is supported by the main body and covers the opening and defines a center hole and a number of gas holes. The heat end passes through the center hole. The main body, the heat body, and the cover are made of thermal conductive refractory material.

### BACKGROUND

1. Technical Field

The present disclosure relates to a vapor deposition system and method, and a crucible used in the system and method.

2. Description of Related Art

In a vapor deposition system, a thermal resistor or an electron gun is usually used to heat and vaporize coating material. When heated by the thermal resistor, the coating material may chemically react with the thermal resistor to produce impurities.

When using the electron gun to heat the coating material, the quality is effected as the coating material usually cannot be heated evenly.

Therefore, it is desirable to provide a crucible, a vapor deposition system and a deposition method, which can overcome the limitations described.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, isometric view of a crucible according to an embodiment of the present disclosure.

FIG. 2 is an exploded view of the crucible of FIG. 1.

FIG. 3 is a sectional view of the crucible of FIG. 1.

FIG. 4 is a cross-sectional view of a vapor deposition system according to an embodiment.

FIG. 5 is a flow chart of a vapor deposition method according to an embodiment.

### DETAILED DESCRIPTION

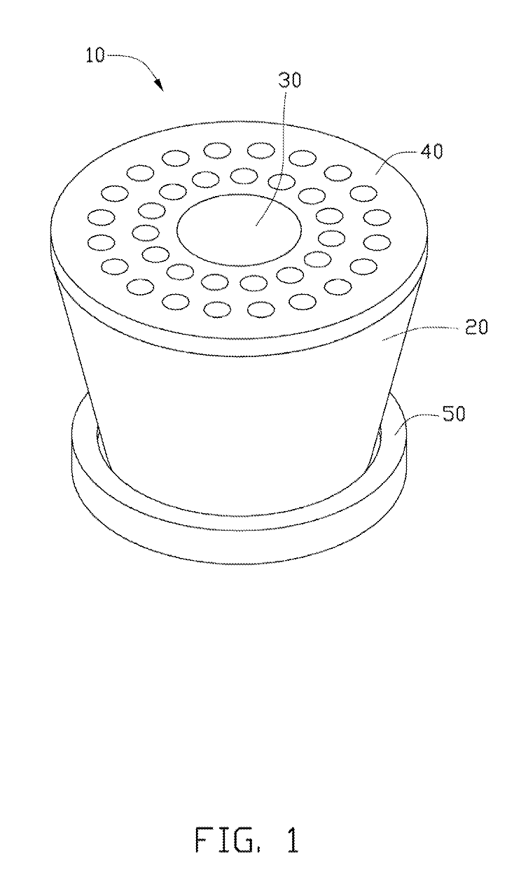

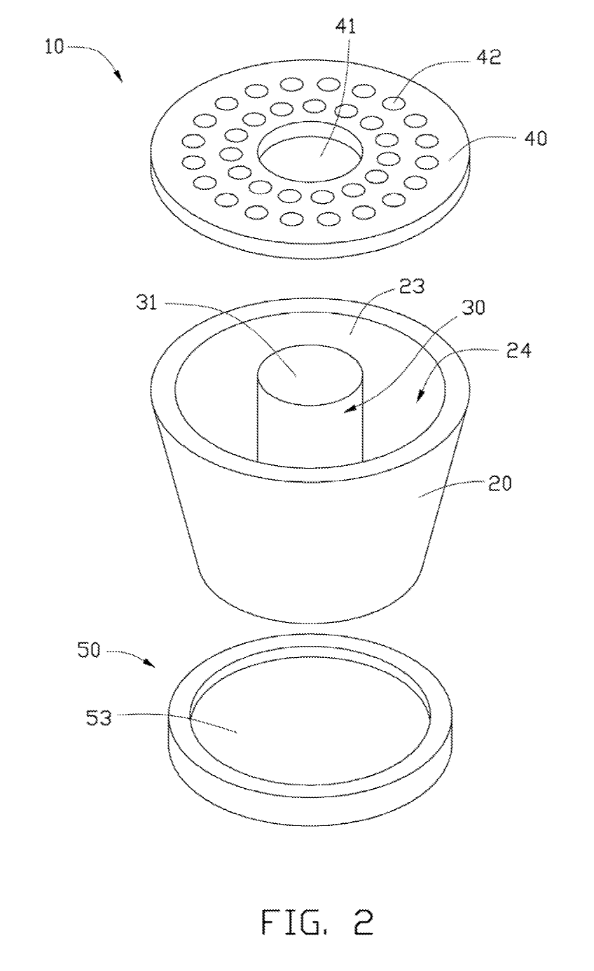

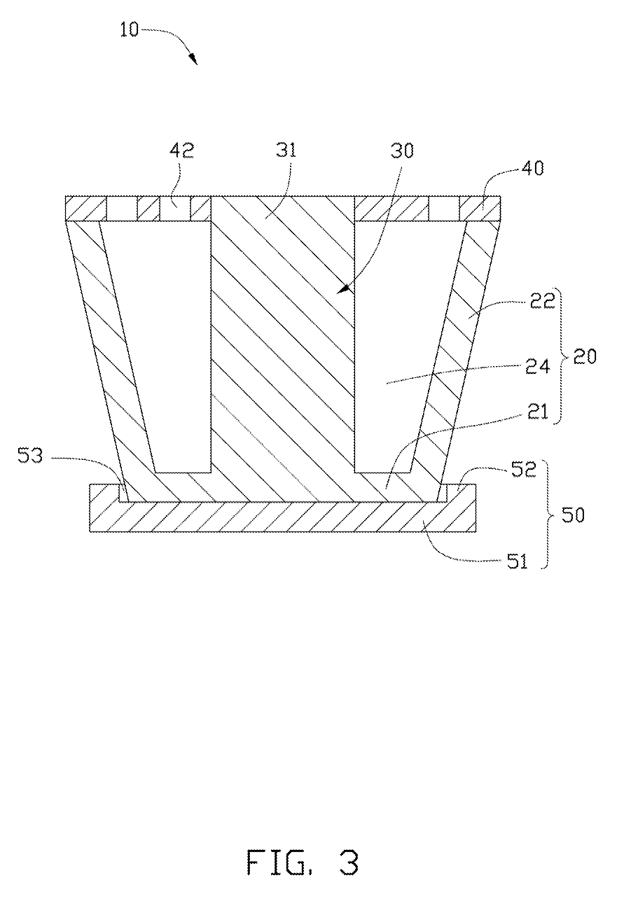

Referring to FIGS. 1 to 3, a crucible 10 according to an embodiment is disclosed. The crucible 10 includes a main body 20, a heat body 30, a cover 40, and a thermal isolation dish 50.

The main body 20 is hollow, and includes a bottom wall 21 and a frustoconical shaped sidewall 22 extending from the bottom wall 21. The sidewall 22 defines an opening 23 opposite to the bottom wall 21.

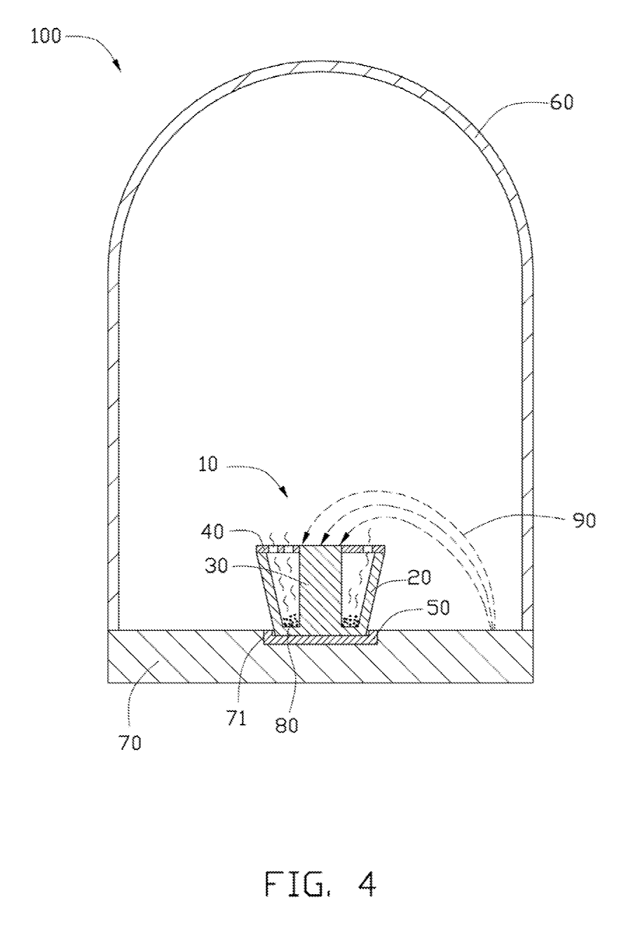

The heat body 30 is received in the main body 20 and is connected with the main body 20. The heat body 30 and the main body 20 cooperatively form a receiving space 24 for receiving coating material 80 (see FIG. 4). In this embodiment, the heat body 30 is cylindrically shaped and is connected with the bottom wall 21 and surrounded by the sidewall 22. The heat body 30 includes a heat end 31 extending out of the main body 20 through the opening 23.

The cover 40 is annular shaped, and defines a center hole 41 and a plurality of gas holes 42. The plurality of gas holes 42 surround the center hole 41. The cover 40 covers the opening 23 and is supported by the sidewall 22. The heat end 31 passes through the center hole 41 and is exposed out of the cover 40.

The main body 20, the heat body 30, and the cover 40 are made of thermally conductive refractory material, such as tungsten, molybdenum, or platinum.

The thermal isolation dish 50 includes a bottom plate 51 and an enclosed sidewall 52 extending from the bottom plate 51. The sidewall 52 defines an opening 53 opposite to the bottom plate 51. The size of the opening 53 is bigger than that of the bottom wall 21 of the main body 20 so that the main body 20 can be put in the thermal isolation dish 50. The thermal isolation dish 50 is made of thermal insulating refractory material, such as porcelain or graphite.

Referring to FIG. 4, a vapor deposition system 100 according to an embodiment is disclosed. The vapor deposition system 100 includes a housing 60, an electron gun seat 70, and the crucible 10. The electron gun seat 70 is mounted in the housing 60. The electron gun seat 70 defines a depression 71. The shape and scale of the depression 71 is substantially the same as those of the thermal isolation dish 50. The thermal isolation dish 50 is received in the depression 71, and the main body 20 is received in the thermal isolation dish 50. In this way, the main body 20 does not contact with the electron gun seat 70.

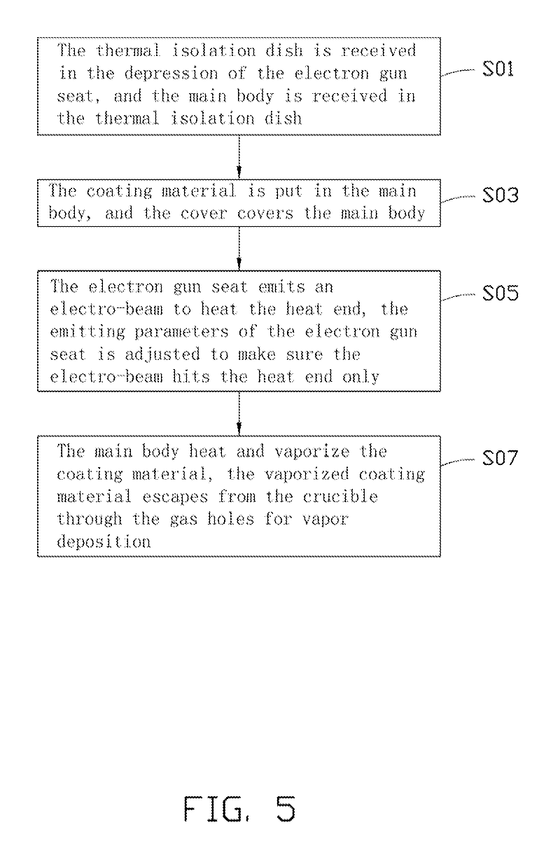

Referring also to FIG. 5, a vapor deposition method according to an embodiment is disclosed. The vapor deposition method includes the following steps:

In step S01, the thermal isolation dish 50 is received in the depression 71 of the electron gun seat 70, and the main body 20 is received in the thermal isolation dish 50, the main body 20 does not contact with the electron gun seat 70.

In step S03, the coating material 80 is put in the receiving space 24 of the main body 20, and the cover 40 covers the main body 20.

In step S05, the electron gun seat 70 emits an electro-beam 90, the electro-beam 90 is guided by a magnetic field and hits the heat end 31 to heat the heat end 31. The magnetic field and the emitting parameters of the electron gun seat 70 are adjusted to make sure the electro-beam 90 can only hit the heat end 31. The operation of the electron gun seat 70 is familiar to one of ordinary skilled in the art, thus, a detailed description is omitted here.

In step S07, the heat body 30 transmits heat to the main body 20. The heat body 30 and the main body 20 work in cooperation to heat and vaporize the coating material 80, and the vaporized coating material 80 escapes from the crucible 10 through the gas holes 42 of the cover 40 for vapor deposition.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A crucible comprising:
a hollow main body defining an opening;
a heat body received in and connected with the main body, the heat body comprising a heat end extending out of the main body through the opening, the heat end configured for being heated by an electro-beam; and
a cover covering the opening and supported by the main body, the cover defining a center hole and a number of gas holes, the heat end passing through the center hole; wherein
the main body, the heat body, and the cover are made of thermal conductive refractory material.

2. The crucible of claim 1, further comprising a thermal isolation dish made of thermal insulating refractory material, the thermal isolation dish supporting the main body.

3. The crucible of claim 2, wherein the thermal isolation dish is made of material selected from the group consisting of: porcelain and graphite.

4. The crucible of claim 1, wherein the main body, the heat body, and the cover are made of material selected from the group consisting of: tungsten, molybdenum, and platinum.

5. A vapor deposition system comprising:
a housing;
an electron gun seat mounted in the housing, and defining a depression; and
a crucible comprising:
a thermal isolation dish received in the depression and supported by the electron gun seat;
a hollow main body positioned on the thermal isolation dish, and defining an opening;
a heat body received in and connected with the main body, the heat body comprising a heat end extending out of the main body through the opening, the heat end configured for being heated by an electro-beam; and
a cover supported by the main body and covering the opening, the cover defining a center hole and a number of gas holes, the heat end passing through the center hole; wherein
the main body, the heat body, and the cover are made of thermal conductive refractory material, and the thermal isolation dish is made of thermal insulating refractory material.

6. The vapor deposition system of claim 5, wherein the main body, the heat body, and the cover are made of material selected from the group consisting of: tungsten, molybdenum, and platinum.

7. The vapor deposition system of claim 5, wherein the thermal isolation dish is made of material selected from the group consisting of: porcelain and graphite.

8. A vapor deposition method, comprising steps of:
providing a crucible, the crucible comprising:
a hollow main body defining an opening;
a heat body received in and connected with the main body, the heat body comprising a heat end extending out of the main body through the opening; and
a cover defining a center hole and a number of gas holes, all of the main body, the heat body, and the cover made of thermal conductive refractory material;
putting coating material in the main body,
covering the opening by using the cover, with the cover supported by the main body and the heat end passing through the center hole; and
emitting an electro-beam to heat the heat end such that the heat body and the main body is heated to vaporize the coating material to escape out of the crucible through the gas holes.

9. The vapor deposition method of claim 8, wherein the crucible comprises a thermal isolation dish made of thermal insulating refractory material, the thermal isolation dish supports the main body.
